(19) United States
(12) Patent Application Publication
(10) Pub. No.: US 2023/0194639 A1
(43) Pub. Date: Jun. 22, 2023

(54) METHOD FOR ACQUIRING A MAGNETIC RESONANCE IMAGE DATASET OF A SUBJECT AND MAGNETIC RESONANCE IMAGING SYSTEM

(71) Applicant: Siemens Healthcare GmbH, Erlangen (DE)

(72) Inventors: Thorsten Feiweier, Poxdorf (DE); Mario Zeller, Erlangen (DE); Bryan Clifford, Malden, MA (US); Zahra Hosseini, Atlanta, GA (US); Adam Kettinger, Erlangen (DE); Simon Bauer, Baunach (DE); Nadine Dispenza, Erlangen (DE)

(73) Assignee: Siemens Healthcare GmbH, Erlangen (DE)

(21) Appl. No.: 17/552,900

(22) Filed: Dec. 16, 2021

(51) Int. Cl. G01R 33/54; G01R 33/42; G01R 33/58; G01R 33/561

(52) U.S. Cl. CPC G01R 33/543; G01R 33/42; G01R 33/583; G01R 33/5613

(57) ABSTRACT

The invention relates to a method for acquiring a magnetic resonance image dataset of a subject, a magnetic resonance imaging system and a non-transitory computer-readable medium. The method comprises the steps:
(a) determining scan conditions relating to an imaging protocol which is to be carried out on the subject;
(b) based on the scan conditions and/or on predetermined reference parameters, determining whether at least one imaging preparation procedure may be omitted or accelerated to have a shortened duration;
(c) depending on the determination of step (b), omitting or carrying out the least one imaging preparation procedure at the standard or at the shortened duration;
(d) carrying out the imaging protocol in order to acquire the magnetic resonance image dataset.

### BACKGROUND OF THE INVENTION

The invention relates to a method for acquiring a magnetic resonance image dataset of a subject, a magnetic resonance imaging system and a non-transitory computer-readable medium.

Magnetic resonance imaging (MRI) is very sensitive e.g. to inhomogeneities in the main (B0) magnetic field. It is therefore important to optimize the imaging conditions in order to obtain images with good diagnostic quality in a clinical environment. For this reason, according to the state of the art, it is common practice for scanner routines to automatically and always apply certain imaging preparation procedures, such as B0 shimming and/or preparation scans before a scan.

On the other hand, one aims at decreasing the examination duration, for example to provide faster examinations in emergency situations and/or to be able to examine a larger number of patients per day. Recent technological advancements, e.g., comprising AI-enhanced reconstructions, have led to considerably decreased examination durations. For example, B. Clifford et al. have shown in “Clinical evaluation of an AI-accelerated two-minute multi-shot EPI protocol for comprehensive high-quality brain imaging,” ISMRM, 2021, pp 1131, that the scan duration of a complete multi-shot EPI (Echo-planar imaging) based head examination may be as short as two minutes. These methods may for example be used in an emergency room setting and/or for scanning uncooperative subjects such as young children. Nevertheless, it is still desirable to further decrease the duration of a complete MRI examination, wherein due to the now much shorter time scales even a decrease of less than a minute or even just a few seconds may be useful.

It is therefore an object of the invention to provide a method for acquiring a magnetic resonance image dataset that may further decrease the duration needed for an MRI examination. It is a further object to provide a possibility to adapt the duration of an examination to the clinical requirements.

### SUMMARY OF THE INVENTION

This object is met or exceeded by a method according to claim 1, a magnetic resonance imaging system according to claim 13, and a non-transitory computer-readable medium according to claim 20. Further advantages and features can be derived from the dependent claims, the description and the attached figures.

According to a first aspect of the invention, a method for acquiring a magnetic resonance image dataset of a subject with a magnetic resonance imaging system is provided. The method comprises the steps:
(a) determining scan conditions relating to an imaging protocol which is to be carried out on the subject;
(b) based on the scan conditions and/or on predetermined reference parameters, determining whether at least one imaging preparation procedure may be omitted or accelerated to have a shortened duration;
(c) depending on the determination of step (b), omitting or carrying out the least one imaging preparation procedure at the standard or at the shortened duration;
(d) carrying out the imaging protocol in order to acquire the magnetic resonance image dataset.

The subject may for example be a human, in particular a patient, or an animal or part of a human or animal. The at least one imaging preparation procedure may be a process which is usually carried out before the actual acquisition of the magnetic resonance image (MRI) dataset during the imaging protocol. The at least one imaging preparation procedure may have the function to improve the image quality and/or the robustness of the MRI data acquisition. The type of the at least one imaging preparation procedure and/or the number of imaging preparation procedures that are usually applied may depend on the imaging protocol. According to the state of the art, imaging preparation procedures are usually automatically carried out before the actual imaging protocol without any regard on the individual scan conditions. Hence, even if the imaging protocol is very fast, e.g., 1 to 2 minutes, and/or does not require very high quality, e.g., is supposed to just give a rough overview, the (unmodified) imaging preparation procedure is carried out regardless, according to the state of the art. Advantageously, the inventive method allows an adaptation of the imaging preparation procedure according to the actual needs of the imaging protocol and therefore an additional possibility to save time. Hence, the at least one imaging preparation procedure is already available but additional steps, in particular steps (a) and (b), are added which determine whether the at least one imaging preparation procedure can be omitted or accelerated in step (c). Accordingly, scan conditions may be determined that justify a compromise in the MRI dataset quality and/or in image quality, in particular by checking predetermined reference parameters. Predetermined reference parameters may be provided via a network, the internet and/or via a server. Additionally and/or alternatively, the predetermined reference parameters may be stored on or at a local processing device and/or on the magnetic resonance imaging system. There may be an option for a user to enter and/or adjust at least some of the predetermined reference parameters.

The determining of the scan conditions and/or the determining of whether at least one imaging preparation procedure may be omitted or accelerated may be carried out automatically. Any of the steps of the method may be carried automatically, e.g., by a processing unit, wherein the processing unit may be comprised by the MRI system. An omission may mean that at least one of one or several imaging preparation procedures usually provided for the imaging protocol is not carried out at all. This may for example be useful, if the at least one imaging preparation procedure provides an improved accuracy which does not have a significant effect on the acquired MRI dataset, e.g., due to the imaging protocol itself being accelerated, or which is not necessary for a required diagnosis. An acceleration may mean that the duration of the at least one imaging preparation procedure is decreased. The decrease in duration may for example be achieved by omitting individual steps and/or repetitions of the at least one imaging preparation procedure and/or by decreasing the applied time of the single steps and/or repetitions. The decrease in duration may be regarded as compared to a standard duration of the at least one imaging preparation procedure. The standard duration may for example be a duration which is usually applied for a particular imaging preparation procedure. Additionally and/or alternatively, the standard duration may be a duration which is predetermined for a specific type of imaging protocol and/or for all types of imaging protocols.

The imaging protocol may be an imaging sequence for acquiring one or several image datasets of the subject. The imaging sequence may be of a fast type such as turbo-spin echo, gradient-echo such as FLASH, HASTE, echoplanar imaging and may include parallel imaging or simultaneous multi-slice imaging. The imaging protocol's scan conditions may include the sequence type, duration, Field-of-view, or any other parameters relating to an imaging sequence, such as TR and TE.

The inventive method may in particular be useful for imaging protocols that have themselves already a very short duration, e.g., 60 to 90 seconds, such that the duration of the at least one imaging preparation procedure is a significant contribution to the duration of the whole MRI examination or acquisition. Very fast imaging protocols may in particular become more common with the availability of AI-enabled reconstruction methods and growing interest in utilizing MRI in time-sensitive applications. In other words, the inventive idea recognizes that the duration of the at least one imaging preparation procedure may no longer be negligible with the now improved speed of some imaging protocols or variants of some imaging protocols. Hence the inventive method provides a solution to further decrease the total acquisition time. This may in particular be advantageous since rapid examination techniques, having a shortened duration of the imaging protocol, that have developed recently are usually applied for clinical questions with reduced requirements regarding image quality in at least some aspect. For example, in an emergency room setup and/or for stroke imaging, it may be sufficient and/or clinically acceptable to obtain MRI datasets with a quality which is “just sufficient” for diagnosis. The same holds true for the scanning of uncooperative subjects, e.g., young children. In these cases, it may be acceptable to provide images with a reduced quality. On the other hand, a decreased duration, as may be provided via the inventive method, may be crucial and/or very beneficial, e.g., due to time constraints.

The inventive method may be repeated once or more than once in order to carry out multiple imaging protocols. In particular, a complete examination of the subject, e.g., a brain examination may comprise multiple cycles as described by the method steps. Some of the steps, in particular steps (a) and (b) may be carried out only once and/or as a combined step (a) and/or a combined step (b) (which may be denoted step (a′) and/or step (b′)), while other steps, in particular steps (c) and (d) may be carried out every time when multiple imaging protocols are applied. In other words, the determination, whether an acceleration and/or an omission of the at least one imaging preparation procedure is applied may be carried out before any of the other steps, procedures and/or scans of multiple cycles are carried out. A complete examination or MRI examination may mean the complete procedure executed on the patient at a time, in particular including the whole time spent by the patient in the MRI system or on the patient table.

The inventive method may for example be applied to echoplanar imaging (EPI) sequence types. EPI is an imaging protocol that may allow the acquisition of MR slices within <100 milliseconds. Therein, following an RF excitation pulse, quickly alternating frequency-encoding gradients are applied in coordination with phase-encoding gradients applied at each alternation. A complete k-space plane may be scanned following one RF excitation (single-shot EPI) or in a few RF excitations (multi-shot EPI). EPI may require at least one imaging preparation procedure for example to achieve fat suppression and/or an improved geometric accuracy. Due to the potentially short duration of EPI, the duration of the at least one imaging preparation procedure may significantly contribute to the total examination time. Even durations of just a few seconds may be significant relative to the duration of the EPI imaging protocol. Accordingly, the inventive method may be particularly advantageous for EPI. However, the method may also be applied to other imaging protocols, in particular to any sequence type and/or imaging protocol with a sensitivity to non-ideal imaging conditions and/or a short duration, e.g., less than 3 minutes, more preferably less than 2 minutes or even less than one minute for the acquisition of a 3D image dataset or a set of 2D image datasets.

According to an embodiment, the at least one imaging preparation procedure comprises at least one scanner adjustment procedure and/or at least one preparatory scan. The scanner adjustment procedure may be termed “extra-scan procedure”. The scanner adjustment procedure may be applied at any time before an actual scan of the image protocol is carried out. The preparatory scan may be termed “intra-scan procedure”. The preparatory scan may be a scan that is carried out directly before the, or each, imaging scan in the examination protocol.

According to an embodiment, the at least one imaging preparation procedure comprises at least one scanner adjustment procedure and/or at least one preparatory scan, wherein the at least one scanner adjustment procedure comprises an adjustment of the center RF frequency, an estimation of an RF transmitter reference voltage, a B1 field shimming, a receive coil sensitivity mapping, and/or a B0 field shimming. The purpose of the center RF frequency's adjustment is in particular to determine the resonance frequency at which protons to be examined are resonating in the actual imaging volume. This value may depend on the tissue to be examined, e.g., protons of water and protons of fat have a slightly different resonance frequency. A dependence on individual patients having varying spatial susceptibility distribution may have a considerable effect on the resonance frequency as well. A standard duration for the adjustment of the center RF frequency may for example be in the range of 2 to 10 seconds, preferably 3 to 5 seconds. The estimation of an RF transmitter reference voltage may in particular have the purpose to determine the voltage needed to cause a specific spin flip angle, e.g., 90° or 180°. The transmitter reference voltage applied on an RF transmission coil may determine the magnitude of the magnetic field B1 used for the RF pulse. On the other hand, the B0 field is the main magnetic field of the MRI system. The purpose of the B0 field shimming is in particular to create a more homogeneous B0 field. The B0 field shimming may comprise directing adjustment currents through coils, e.g., shim coils and or imaging gradient coils, in order to adjust the B0 field. A standard duration for B0 field shimming may for example be in the range of 3 to 60 seconds, preferably 5 to 30 seconds. B0 field shimming may be useful to accommodate for field variations due to a change of table positioning, and/or a change of tissue and/or shape of the studied region. These scanner adjustment procedures may all be used to improve the scan quality. However, in order to save time, it may be advantageous to omit and/or accelerate the scanner adjustment procedures. The determining of whether at least one imaging preparation procedure may be omitted or accelerated may be further based on a predetermined importance or influence of the scanner adjustment procedures for specific imaging protocols and/or on a predetermined or user input requirement on image quality. The requirement on image quality may be determined based on user selected scan duration requirements (e.g., limits such as a maximum duration) and/or on a database containing information about requirements of imaging protocols and/or variants of a specific imaging protocol. For example, an EPI sequence (single-shot or multishot, respectively) may require a frequency adjustment immediately before each scan in order to guarantee optimum fat suppression efficiency and/or geometric accuracy. This frequency adjustment may be adapted according to the actual imaging protocol, i.e., a quick adjustment may be carried out for short scan durations and a longer, in particular more precise, adjustment may be carried out for long scan durations. For short scan durations, and if a previous frequency adjustment may still be considered valid, the latter may be re-used for the imaging protocol. This condition will typically apply for short examination durations, where the previous frequency adjustment has been executed not long before.

According to an embodiment, when the center RF frequency adjustment is to be omitted, the center RF frequency is set to a value determined in a previous center RF frequency adjustment; and/or, when the B0 field shimming is to be omitted, default shim settings are used. The method may comprise an additional step of logging and saving the imaging protocols and/or at least some scan conditions of the MRI dataset acquisitions in order to create the log file for future MRI dataset acquisitions. The scan conditions may comprise the log file about recently carried out imaging protocols, e.g., a predetermined number of the last imaging protocols, such as the last 10 imaging protocols, and/or imaging protocols carried out during a predetermined time span before the current time, such as during the last 2 hours, in particular during the last 30 minutes. The log file may comprise the previous center RF frequency adjustment and/or the default shim settings. The previous center RF frequency adjustment used to set the value of the RF frequency may be chosen based on a comparison of the current imaging protocol and a previous imaging protocol, such that the same, an equivalent, and/or a similar previous imaging protocol is used. Additionally and/or alternatively, the previous center RF frequency adjustment may be chosen such that more recent center RF frequency adjustments are preferred. Additionally and/or alternatively, the previous center RF frequency adjustment may be chosen based on the examined subject, e.g., a previous center RF frequency adjustment may be chosen that was examining the same body part, the same imaging volume (in particular considering the position and/or orientation of 2D slices or 3D slabs), and/or equivalent types of tissue, such as having the same or a similar composition of body fat and water. Additionally and/or alternatively, in a series of imaging protocols, in particular same, similar, and/or equivalent imaging protocols, the frequency adjustment may be carried out only before the first imaging protocol and omitted before the following imaging protocols. For example, rather than running a frequency adjustment before each imaging protocol in a series of 4 imaging protocols, the frequency adjustment gets executed only once at the beginning. Accordingly, this may reduce the total examination time by 3 times the duration of one frequency adjustment, e.g., by about 10 seconds. The default shim settings may be obtained and/or set during installation of the magnetic resonance imaging system, in particular of the magnetic resonance scanner. Additionally and/or alternatively, the default shim settings may be based on a previous B0 field shimming and/or a combination of a previous B0 field shimming together with the shim settings set during installation of the magnetic resonance imaging system. The previous B0 field shimming used for the default shim settings may be chosen such that the previous B0 field shimming was done under similar conditions as are currently prevalent. Similar conditions may correspond to the imaging protocol, the scan conditions, in particular table positioning and/or the object or subject, e.g., wrist, ankle, head etc., to be examined. There may be a plurality of default shim settings which are to be used for different imaging protocols and/or for different scan conditions. An acceleration of the B0 field shimming may comprise switching to a faster shim adjustment scan, for example by reducing the resolution of the shim adjustment scan. When the adjustment of the center RF frequency is omitted, a setting from a database, in particular based on the subject to be examined, and/or a previous setting may be used.

According to an embodiment, the at least one imaging preparation procedure comprises at least one scanner adjustment procedure and/or at least one preparatory scan, wherein the at least one preparatory scan comprises one or several dummy scans to establish a steady state of the magnetization and/or auto-calibration scans to estimate coil sensitivity maps. The dummy scan(s) may also be denoted as a preparation scan which is carried out before the actual scan of the imaging protocol. The dummy scan(s) may in particular have the function to avoid fluctuations of the steady state of the magnetization during imaging scans of the imaging protocol. After starting to scan it may take a while, in particular a few seconds, until a steady state of the magnetization is reached. Hence, applying one or several dummy scan(s) before the actual scan of the imaging protocol may ensure that during the actual scan the steady state is already reached or at least mostly reached. If the steady state is not reached at the beginning of the actual scan, this may lead to image blurring and/or to aliasing artifacts. Several dummy scans are needed in order to reach the steady state before the start of the actual scan of the imaging protocol. The duration of the dummy scan may depend on the selected imaging TR (repetition time of the MRI scan), wherein the selected TR of the dummy scan may be the same TR as the TR of the actual scan according to the imaging protocol. The duration of the one or several dummy scans may be adapted by adapting the number of dummy scans. The one or several dummy scans may be accelerated by reducing the number of dummy scans and/or by reducing the minimum duration which is considered for calculating the number of required dummy preparation scans. An acceleration and or reduction of the duration may for example be provided by reducing the minimum duration to 2 seconds (e.g., from a standard duration of originally 4 seconds). Accordingly, for a selected TR of, e.g., 2 seconds or higher, a single dummy scan may be requested (rather than two dummy scans for 4 sec>TR>2 sec). Accordingly, the total scan time of the whole imaging process may be reduced by 1×TR in this example. According to an exemplary embodiment, the scan time/duration of the imaging protocol may be a scan condition, and the one or several dummy scans may be adapted according to the scan time, in particular such that a short scan time leads to an acceleration of the one or several dummy scans. An imaging protocol that has been executed directly before the current imaging protocol may be a scan conditions that may lead to determining that the duration of the one or several dummy scans may be reduced and/or the one or several dummy scans may be omitted. Omitting the one or several dummy scans according to some scan conditions and/or predetermined reference parameters may lead to a compromise in image quality. A scan condition leading to omitting the one or several dummy scans may be an information, e.g., input by a user or stored in a database with regard to specific imaging protocols and/or scan conditions, that an imaging protocol and/or a particular variant of an imaging protocol does not necessitate a very high image quality and/or does not require a maximally unblurred and/or aliasing free image.

Auto-calibration scans (ACS) may for example be used for parallel imaging purposes, in which coil sensitivity profiles are used to accelerate the imaging protocol by acquiring less k-space data. ACS may be carried out by acquiring images, in particular low-resolution images, for each imaging coil separately and for the full field of view. The low-resolution images may then be normalized, e.g., by a full body coil image, in order to get coil sensitivity maps. The coil sensitivity maps may be used to determine a weighting of signals from different locations in the field of view for each coil. The amount of acquired ACS data may determine the quality of generated images. An acceleration may for example be achieved by decreasing the time of ACS acquisition. This may lead to less accurate coil sensitivity maps but may be acceptable for some applications and/or examinations. The ACS acquisition duration may for example be in the range of 1 to 30 seconds, preferably 2 to 20 seconds.

According to an embodiment the at least one preparatory scan comprises auto-calibration scans to estimate coil sensitivity maps. If the auto-calibration scans are to be omitted, coil sensitivity profiles are estimated from other sources, in particular from an adjustment scan; and/or, if the autocalibration scans are to be accelerated, the duration of the auto-calibration scans is adjusted to be shorter by reducing the resolution of the auto-calibration scans. The adjustment scan may for example be a B0 field shimming as described above. Using adjustment scans may be sufficient to provide reference data to determine coil sensitivities. Compromises due to lower resolution of the accelerated auto-calibration scans and/or due to different scan orientations of the adjustment scans may degrade the image but may be acceptable for some situations, in particular in situations where saving time is important.

According to an embodiment, the scan conditions comprise the duration of the imaging protocol, the purpose of a scan of the imaging protocol, and/or the sequence type/or a type of a scan mode of the imaging protocol. The duration may for example be considered such that a shorter duration of the imaging protocol may be a reason to accelerate and/or omit the at least one imaging preparation procedure. This may be advantageous because in case of an imaging protocol with a shorter duration, the duration of the at least one imaging preparation procedure has a greater relative impact on the total duration. Furthermore, imaging protocols with a shorter duration may have more focus on speed, wherein accuracy may be less important. The purpose may constitute an implicit dependence on scan parameters. For example, if the scan parameters are set such that the scan will be faster than average scans of this type and/or that the resolution and/or image quality is lower than an average value, this may be a cue to accelerate and/or omit the at least one imaging preparation procedure. Properties of average scans and/or average values may for example be stored on a database and/or serve as predetermined reference parameters. In particular a “fast reference scan” option chosen by a user, may be taken as indications that a compromise in image quality is acceptable and thus trigger an omission and/or acceleration of at least one imaging preparation procedure. The option set may be regarded as an implicit command to accelerate and/or omit the at least one imaging preparation procedure. There may be provided multiple options for a user to choose, e.g. related to the acquisition of ACS lines, and choosing a short duration for the imaging protocol (e.g., lower than a predetermined threshold) and/or a “fast reference scan” option may trigger the omission and/or acceleration. The sequence or type of a scan mode of the imaging protocol may for example be a parallel imaging technique, e.g., GRAPPA (GeneRalized Autocalibrating Partial Parallel Acquisition), echo-planar imaging, spin echo, turbo spin echo (TSE) and/or gradient echo. For example, in the case of parallel imaging, auto-calibration scans and/or B0 field shimming may be more important than with other modes, e.g., TSE, and, hence, the auto-calibration scans may be generally accelerated to a lesser degree and or be less likely to be omitted for parallel imaging than for other scan modes. Several scan conditions may be regarded in combination in order to determine whether and/or how an acceleration and/or an omission is to be applied. For example, according to one exemplary embodiment, an acceleration and/or an omission may only be applied if more than one specific scan conditions fulfill predetermined reference parameters. Additionally and/or alternatively, a level of acceleration may be determined based on several scan conditions and their comparison with predetermined reference parameters.

According to an embodiment, the predetermined reference parameters are one or more of the following:
a predetermined upper threshold of an imaging protocol duration,
a databank of predetermined possible user input commands relating to scan conditions,
a databank of purposes for different imaging protocols, and/or
a databank of known types of different scan modes.

The upper threshold of an imaging protocol duration may be used in particular such that, if the imaging protocol duration is below the upper threshold, the at least one imaging preparation procedure is omitted and/or accelerated. There may be several upper thresholds and different degrees of acceleration may be connected to the several upper thresholds, in particular such that lower thresholds correspond to a greater acceleration than higher thresholds. Optionally, a lowest threshold may correspond to the omission of the at least one imaging preparation procedure. The predetermined upper threshold or several predetermined upper thresholds corresponding to different imaging protocol may be stored on a database, in particular the databank of known types of different scan modes. The upper threshold may be in the range of 10 seconds to 2 minutes, for example 30 seconds. The databank of predetermined user commands may comprise instructions to accelerate and/or omit the at least one imaging preparation procedure when some of the predetermined user commands are input by a user. The user commands may in particular be relating to image quality, image resolution and/or the duration of the imaging protocol. Hence, a user may be provided with multiple options, for example on a graphical user interface (GUI) with which the imaging protocol is planned, e.g. related to the duration of the imaging protocol (e.g., lower than a predetermined threshold) and/or a “fast reference scan” and choosing one or several of these options may be regarded as trigger for the omission and/or acceleration. The databank of purposes may comprise information about the purpose of the imaging protocols. In particular, the purpose may be a medical indication, such as “suspected stroke” or “suspected fracture”, or may contain information on the type of patient (e.g. “infant”, “uncooperative”) or body part (e.g. “knee” or “head”). Accordingly, the databank of purposes may comprise instructions for which image protocol and/or under what conditions the at least one imaging preparation procedure can be accelerated and/or omitted and/or to what degree an acceleration is to be applied. The databank of known types may comprise information about the importance of the at least one imaging preparation procedure for the corresponding scan mode. The databank of known types may comprise instructions for which scan mode and/or under what conditions the at least one imaging preparation procedure can be accelerated and/or omitted and/or to what degree an acceleration is to be applied. Advantageously some or all of said predetermined reference parameters may allow to provide an individual adaption of the at least one imaging preparation procedure according to the relevant requirements.

According to an embodiment, the ratio of the duration of the imaging protocol to a standard duration of the at least one imaging preparation procedure is calculated; wherein the ratio is compared to a ratio threshold value; wherein the at least one imaging preparation procedure is determined to be omitted or its duration to be shortened to a predetermined duration below the standard duration when the ratio is below the ratio threshold value. The standard duration may be a predetermined duration that may in particular be applied, when the at least one imaging preparation procedure is not accelerated. The database or databank as mentioned above may comprise information about the standard duration of the at least one imaging preparation procedure. The method may comprise calculating the relative contribution of the at least one imaging preparation procedure to the total acquisition time and omit and/or accelerate the at least one imaging preparation procedure based on said relative contribution. The relative contribution may be calculated by calculating said ratio. For example, if the at least one imaging preparation procedure requires more than a value in the range of 5% to 20%, e.g., 10%, of the total scan time to execute, it may be omitted and/or accelerated. Advantageously, this embodiment allows to take into account the significance of the at least one imaging preparation procedure to the total scan time. Accordingly, it may be possible to only apply the acceleration and/or omission, when the time that is saved does exceed a predetermined significance relative to the total duration. This ratio may be combined with one or several other conditions, e.g., an acceleration and/or omission is only applied if other conditions as described herein are fulfilled, in particular if the omission or acceleration still leads to an acceptable, although lowered, image quality. For example, for parallel imaging, ACS may be accelerated, but preferably not omitted. A B0-shim may be omitted, if previous B0 field shimming data is available. Additionally and/or alternatively the degree of an acceleration may depend on the ratio being below the ratio threshold value and/or additional conditions.

According to an embodiment, the determined scan conditions are compared to the predetermined reference parameters, and a database of comparison rules is used to determine whether the at least one imaging preparation procedure is to be omitted and/or whether the at least one imaging preparation procedure is to be accelerated. The database may be any database and/or databank as described herein. The database may in particular include programmatic rules. Programmatic rules may, for example, comprise conditional commands, such as “IF this THEN that”. The comparison rules may comprise an upper threshold as described herein, in particular corresponding to a duration of the at least one imaging preparation procedure and/or the imaging protocol. Additionally and/or alternatively, the comparison rules may correspond to a type of imaging protocol and/or a variant of a type of imaging protocol, e.g., a fast reference scan.

According to an embodiment, a user is enabled to input a speed-up request when or before selecting the imaging protocol, wherein an input speed-up request is treated as scan condition. An explicit request by the user may be used as a command to accelerate and/or omit the at least one imaging preparation procedure. According to an embodiment, the input speed-up request may be treated as scan condition that requires the at least one imaging preparation procedure to be omitted and/or accelerated. For example, a “Fast Scan” button may be provided to the user, e.g., physically and/or as part of a user interface. The “Fast Scan” button may, when activated, trigger the omitting and/or accelerating of the at least one imaging preparation procedure. Advantageously, a user may thus be enabled to, if necessary, quickly, decide whether a scan should be faster, e.g., in emergency situations.

According to an embodiment, the imaging protocol is a fast imaging protocol, in particular the imaging protocol may use parallel imaging techniques and/or may comprise a single-shot and/or multi-shot echo-planar imaging scan and/or a Half-Fourier-Acquired Single-shot Turbo spin Echo (HASTE) scan and/or a Fast Low-Angle Shot (FLASH) acquisition. A fast imaging protocol may be a protocol that comprises a total examination time for a 3D image dataset or a set of 2D images of up to 3 minutes, preferably up to 2 minutes, and more preferably up to 1 minute.

According to a further aspect of the invention, a magnetic resonance imaging system comprising a processing unit configured to carry out the following operations is provided:
(a) determining scan conditions relating to an imaging protocol which is to be carried out on the subject;
(b) based on the scan conditions and/or on predetermined reference parameters, determining whether at least one imaging preparation procedure may be omitted or accelerated to have a shortened duration;
(c) depending on the determination of step (b), omitting or carrying out the least one imaging preparation procedure at the standard or at the shortened duration;
(d) carrying out the imaging protocol in order to acquire the magnetic resonance image dataset.

The processing unit may be a computer or may be part of a computer. The computer may be a PC, a server, a console of an MRI apparatus. The computer may also be a mobile device, such as a laptop, tablet computer or mobile phone. All features and advantages of the method may be adapted to the magnetic resonance imaging system and vice versa.

According to an embodiment, the magnetic resonance imaging system is further configured such that the at least one imaging preparation procedure comprises at least one scanner adjustment procedure, and that the least one scanner adjustment procedure comprises an adjustment of the center RF frequency, an estimation of a RF transmitter reference voltage, a B1 field shimming, a receive coil sensitivity mapping and/or a B0 field shimming.

According to an embodiment, the processor is further configured such that, when the center RF frequency adjustment is to be omitted, the center RF frequency is set to a value determined in a previous center RF frequency adjustment; and/or that, when the B0 field shimming is to be omitted, default shim settings are used.

According to an embodiment, the processor is further configured such that the at least one imaging preparation procedure comprises at least one preparatory scan, wherein the at least one preparatory scan comprises one or several dummy scans to establish a steady state of the magnetization and/or autocalibration scans to estimate coil sensitivity maps.

According to an embodiment, the processor is further configured such that, if the auto-calibration scans are to be omitted, coil sensitivity profiles are estimated from other sources, in particular from an adjustment scan; and/or wherein the processor is further configured such that, if the auto-calibration scans are to be accelerated, the duration of the auto-calibration scans is adjusted to be shorter by reducing the resolution of the auto-calibration scans.

According to an embodiment, the processor is further configured such that the scan conditions comprise the duration of the imaging protocol, the purpose of a scan of the imaging protocol, and/or the type of a scan mode of the imaging protocol.

According to an embodiment, the predetermined reference parameters are one or more of the following:
a predetermined upper threshold of an imaging protocol duration,
a databank of predetermined possible user input commands relating to scan conditions,
a databank of purposes for different imaging protocols, and/or
a databank of known types of different scan modes.

According to a further aspect of the invention, a computer program comprising instructions, which, when the program is executed by a processing unit of a magnetic resonance imaging system, causes the processing unit to carry out the method as described herein is provided. All features and advantages of the method and the magnetic resonance imaging system may be adapted to the computer program and vice versa.

According to a further aspect, a non-transitory computer-readable medium is provided. The non-transitory computer-readable medium has stored thereon a computer program which, when the program is executed by a processing unit of a magnetic resonance imaging system, causes the processing unit to carry out the following operations:
(a) determining scan conditions relating to an imaging protocol which is to be carried out on the subject;
(b) based on the scan conditions and/or on predetermined reference parameters, determining whether at least one imaging preparation procedure may be omitted or accelerated to have a shortened duration;
(c) depending on the determination of step (b), omitting or carrying out the least one imaging preparation procedure at the standard or at the shortened duration;
(d) carrying out the imaging protocol in order to acquire the magnetic resonance image dataset.

The computer-readable medium may be any digital storage medium, such as a hard disc, a cloud, an optical medium such as a CD or DVD, a memory card such as a compact flash, memory stick, a USB-stick, multimedia stick, secure digital memory card (SD) etc. All features and advantages of the method, the magnetic resonance imaging system, and the computer program may be adapted to the computer-readable medium and vice versa.

All embodiments mentioned herein may be combined with each other. In particular the embodiments corresponding to different features, in particular the scan conditions, the predetermined reference parameters, the at least one imaging preparation procedure, the acceleration and/or omission etc., may be combined with each other and may complement each other.

### BRIEF DESCRIPTION OF THE DRAWINGS

The accompanying drawings illustrate various example methods and other example embodiments of various aspects of the invention.

FIG. 1 is a flow diagram of a method according to an embodiment of the invention;

FIG. 2 is a flow diagram of a method according to another embodiment of the invention; and

FIG. 3 is a schematic illustration of a magnetic resonance imaging system according to an embodiment of the invention.

### DETAILED DESCRIPTION OF EMBODIMENTS WITH REFERENCE TO THE DRAWINGS

Similar elements are designated with the same reference signs in the drawings.

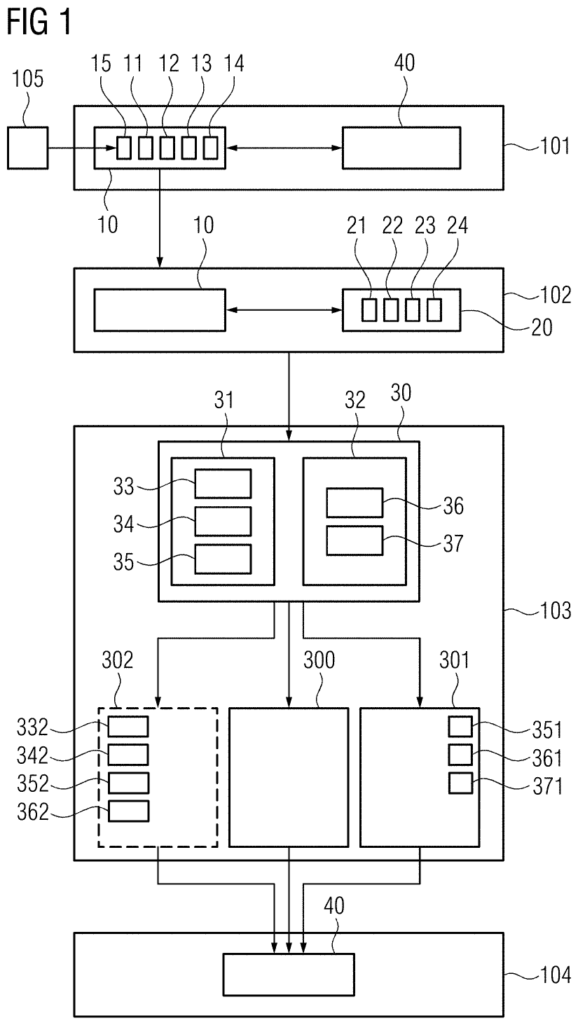

FIG. 1 shows a flow diagram of a method according to an embodiment of the invention. In a first step 101, scan conditions 10 relating to an imaging protocol 40 are determined. The imaging protocol 40 relates to acquiring a magnetic resonance image dataset of a subject with a magnetic resonance imaging system 1. The scan conditions 10 comprise a duration 11 of the imaging protocol 40, a scan-related option set by a user 12, a purpose of the scan 13, and a type of scan mode 14. In an optional step 105, a user may be enabled to input a speed-up request 15 which may then also be treated as a scan condition 10.

In the following step 102 the scan conditions 10 are compared to predetermined reference parameters 20 in order to determine, whether one or several imaging preparation procedures 30 may be omitted or accelerated to have a shortened duration 301. The predetermined reference parameters 20 comprise a predetermined upper threshold of an imaging protocol duration 21, a databank of predetermined possible user input commands relating to scan conditions 22, a databank of purposes for different imaging protocols 23, and a databank of known types of different scan modes 24. Several predetermined reference parameters 20 and scan conditions 10 may be taken into combined consideration in order to determine, whether the imaging preparation procedures 30 are to be accelerated and/or omitted. The imaging preparation procedures 30 may comprise at least one scanner adjustment procedure 31 and/or at least one preparatory scan 32. The at least one scanner adjustment procedure 31 may comprise one or several of an adjustment of the center RF frequency 33, an estimation of an RF transmitter reference voltage 34, a B1 field shimming, a receive coil sensitivity mapping, and/or a B0 field shimming 35. The at least one preparatory scan 32 may comprise one or several of auto-calibration scans 36 to estimate coil sensitivity maps and/or dummy scans 37 to establish a steady state of the magnetization. In particular, a database of comparison rules is used to determine whether the imaging preparation procedures 30 are to be omitted 302 and/or whether the imaging preparation procedures 30 are to be accelerated 301. For example, the ratio of the duration 11 of the imaging protocol 40 to a standard duration 300 of at least one of the imaging preparation procedures 30 may be calculated. This ratio is compared to a ratio threshold value and, when the ratio is below the ratio threshold value, the at least one imaging preparation procedure 30 is determined to be omitted 302 or its duration to be shortened to a shortened duration 301 below the standard duration 300.

In the following step 103, depending on the determination of step 102, the imaging preparation procedures 30 are omitted 302 or carried out at the standard duration 300 or at the shortened duration 301. When an imaging preparation procedure 30 is omitted 302, it may either be completely omitted or replaced by an alternative measure. For example, when the center RF frequency adjustment 33 is to be omitted 302, the center RF frequency may be set to a value determined in a previous center RF frequency adjustment 332. When the B0 field shimming 35 is to be omitted 302, default shim settings may be used 352. When the auto-calibration scans 36 are to be omitted 302, coil sensitivity profiles may be estimated from other sources 362, in particular from an adjustment scan. Acceleration may generally be achieved by simply reducing the duration of the procedure and/or by reducing the resolution. For example, the B0 field shimming 35 may be accelerated by reducing the resolution of the shim adjustment scan 351. Furthermore, if the auto-calibration scans 36 are to be accelerated 301, the duration of the auto-calibration scans may be adjusted to be shorter by reducing the resolution of the auto-calibration scans 361.

Finally, after carrying out and/or omitting the imaging preparation procedures 30, the imaging protocol 40 is carried out in order to acquire the magnetic resonance image dataset in step 104. The imaging protocol 40 may be a fast imaging protocol, in particular the imaging protocol may use parallel imaging techniques and/or may comprise a multi-shot echoplanar imaging scan, a Fast Low-Angle Shot (FLASH) acquisition and/or a Half-Fourier-Acquired Single-shot Turbo spin Echo (HASTE) scan.

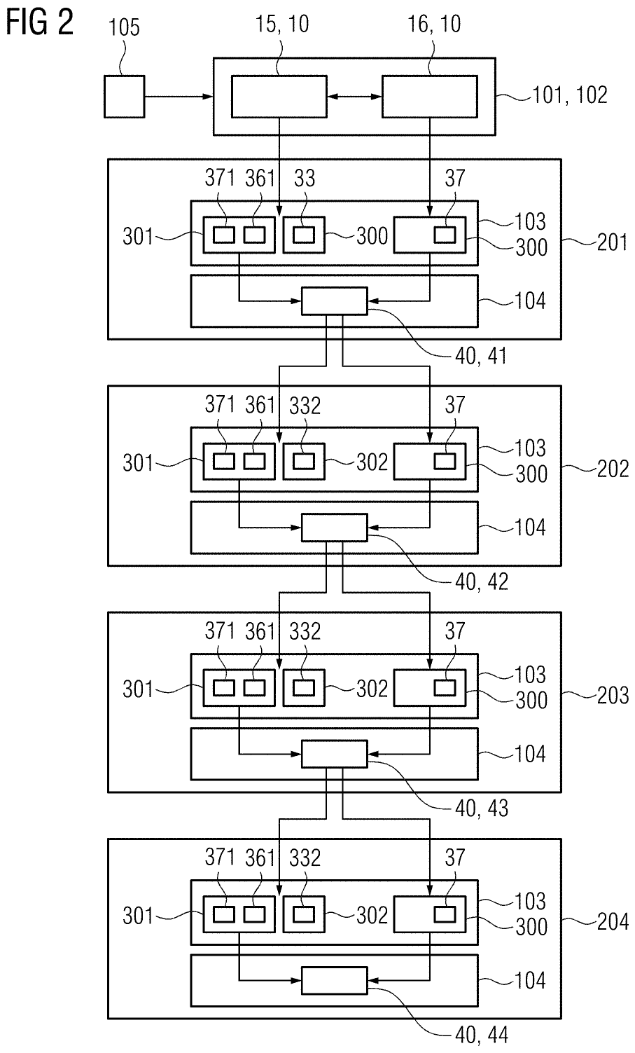

FIG. 2 shows a flow diagram of a method according to another embodiment of the invention. In this embodiment, there are four data acquisition cycles 201-204 that are carried out consecutively. The purpose of these cycles is a brain examination that consists of four imaging protocols 40 which may acquire different contrasts. The first cycle 201 comprises a multi-shot GRE-EPI (gradient echo—echoplanar imaging) scan 41 with inversion-recovery preparation for acquiring images with T1 contrast in about 25 seconds. Additionally and/or alternatively, the first cycle 201 may comprise a GRE (FLASH) acquisition. The second cycle 202 comprises a multi-shot-multi-echo GRE/SE-EPI (gradient echo/spin echo—echoplanar imaging) scan 42 for acquiring images with T2* and T2 contrast in about 25 seconds. The third cycle comprises a multishot SE-EPI (spin echo—echoplanar imaging) scan 43 with inversion-recovery preparation for acquiring images with T2-FLAIR (fluid attenuated inversion recovery) contrast in about 50 seconds. The fourth cycle comprises a single-shot DW-SE-EPI (diffusion weighted—spin echo—echoplanar imaging) scan 44 for acquiring images with diffusion contrast and ADC (apparent diffusion coefficient) maps in about 20 seconds. All scans 41-44 get acquired with parallel imaging techniques (e.g. GRAPPA) which require ACS (auto-calibration scans) lines. The user interface provides a corresponding element in step 105 which allows the user to select different ACS acquisition modes, including in this embodiment, demanding a speed-up request 15 or selecting a standard speed, i.e., no speed-up request 16. In step 101 the user request is treated as scan condition 10 and used in the following step 102 to determine whether imaging preparation procedures 30 are to be omitted or accelerated to have a shortened duration. For this purpose, predetermined reference parameters are the information that a speed-up request will lead to an acceleration 301 and/or omission 302 of at least one imaging preparation procedure 30, while no speed-up request will lead to applying the imaging preparation procedures 30 with a standard duration 300.

In step 103 of the cycles 201-204, if the user selects no speed-up request 16, ACS lines get acquired with high resolution (e.g., the number of columns matching that of the imaging scans) in order to obtain maximum quality at the expense of a longer scan duration. At the same time, imaging preparation procedures with a standard duration 300 which maximize image quality at the expense of a longer examination duration are used. For example, dummy scans 37 may get requested for a minimum of 4 seconds according to a standard duration 300, and the total duration is typically a multiple of the selected imaging TR.

If the user selects a speed-up request 15, ACS lines get acquired with reduced resolution 361 (e.g., just 24 columns) in order to reduce 301 the ACS acquisition time at the expense of a reduced unaliasing performance. Furthermore, enabling the speed-up request 16 will simultaneously trigger the following accompanying changes in order to speed up the total scan time. First, according to this embodiment, during acquisition cycles 202-204, the center frequency from the first acquisition cycle 201 will be used 332. The adjustment of the center RF frequency 33 is omitted 302 during the second to fourth cycle 202-204. Hence an adjustment of the center RF frequency 33 will only be carried out during step 103 of the first cycle 201. Rather than running a frequency adjustment 33 before each imaging protocol 40, a frequency adjustment 33 gets executed only once at the beginning. This may reduce the total examination time by 3 times the duration of the adjustment (e.g., ˜10 seconds). Second, during all cycles 201-204, the minimum dummy preparation scan duration will be reduced 371, e.g., to 2 seconds (rather than e.g., 4 sec).

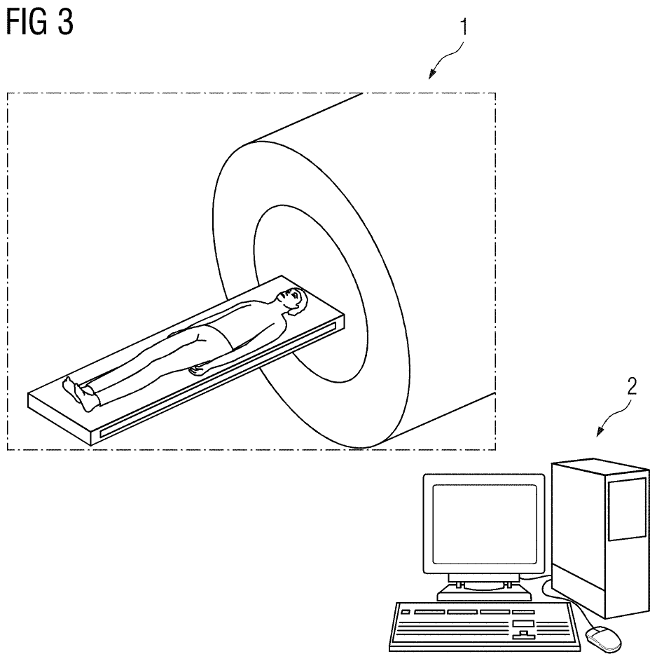

FIG. 3 shows a schematic illustration of a magnetic resonance imaging system 1 according to an embodiment of the invention. The system 1 comprises a processing unit 2 configured to carry out operations according to the method described above. The operations are stored on a non-transitory computer-readable medium that is part of the processing unit 2.

1. A method for acquiring a magnetic resonance image dataset of a subject with a magnetic resonance imaging system, comprising:
determining scan conditions relating to an imaging protocol that is to be carried out on the subject;
based on the scan conditions and/or predetermined reference parameters, performing a determination of whether an imaging preparation procedure may be omitted or accelerated to have a shortened duration, the imaging preparation procedure comprising (i) a scanner adjustment procedure that comprises an adjustment of a center RF frequency, an estimation of an RF transmitter reference voltage, a B1 field shimming, a receive coil sensitivity mapping, and/or a B0 field shimming, and/or tin a preparatory scan;
when the determination of whether the imaging preparation procedure may be omitted or accelerated indicates that the imaging preparation procedure may be omitted, omitting the imaging preparation procedure;
when the determination of whether the imaging preparation procedure may be omitted or accelerated indicates that the imaging preparation procedure may be accelerated, executing the imaging preparation procedure at a standard duration or at the shortened duration that is less than the standard duration; and
executing the imaging protocol to acquire the magnetic resonance image dataset,
wherein (i) when the center RF frequency adjustment is to be omitted, setting the center RF frequency to a value determined in a previous center RF frequency adjustment, and/or (ii) when the B0 field shimming is to be omitted, using default shim settings.

2.-3. (canceled)

4. The method according to claim 1,
wherein the preparatory scan comprises one or more dummy scans to establish a steady slate of magnetization and/or auto-calibration scans to estimate coil sensitivity maps.

5. The method according to claim 4, wherein, if the auto-calibration scans are to be omitted, coil sensitivity profiles are estimated from other sources, which include an adjustment scan; and/or
wherein, if the auto-calibration scans are to be accelerated, the duration of the autocalibration scans is adjusted to be shorter by reducing a resolution of the auto-calibration scans.

6. The method according to claim 1, wherein the scan conditions comprise a duration of the imaging protocol, a scan-related option set by a user, a purpose of a scan of the imaging protocol, and/or a type of a scan mode of the imaging protocol.

7. The method according to claim 6, wherein the predetermined reference parameters are one or more of:
a predetermined upper threshold of an imaging protocol duration,
a databank of predetermined possible user input commands relating to scan conditions,
a databank of purposes for different imaging protocols, and/or
a databank of predetermined types of different scan modes.

8. The method according to claim 1, wherein the scan conditions comprise a duration of the imaging protocol, and further comprising:
calculating a ratio of the duration of the imaging protocol to the standard duration of the imaging preparation procedure;
comparing the ratio to a ratio threshold value; and
determining, when the ratio is below the ratio threshold value, that the imaging preparation procedure is to be omitted or a duration of the imaging preparation procedure is to be shortened to a predetermined duration that is less than the standard duration.

9. The method according to claim 1, further comprising:
comparing the determined scan conditions with the predetermined reference parameters; and
determining whether the imaging preparation procedure is to be omitted and/or the imaging preparation procedure is to be accelerated using a database of comparison rules.

10. The method according to claim 1, wherein a user is enabled to input a speed-up request via a “Fast Scan” button, when or before selecting the imaging protocol, and
wherein an input speed-up request is treated as scan condition.

11. The method according to claim 10, wherein the input speed-up request is treated as scan condition that requires the imaging preparation procedure to be omitted and/or accelerated.

12. The method according to claim 1, wherein the imaging protocol comprises one or more of parallel imaging techniques, a single shot, a multi-shot echo-planar imaging scan, a Half-Fourier-Acquired Single-shot Turbo spin Echo (HASTE) scan, and a Fast Low-Angle Shot (FLASH) acquisition.

13. A magnetic resonance imaging system for acquiring a magnetic resonance image dataset of a subject, the magnetic resonance system comprising a processor configured to execute instructions to cause the magnetic resonance imaging system to:
determine scan conditions relating to an imaging protocol that is to be carried out on the subject;
based on the scan conditions and/or on predetermined reference parameters, perform a determination of whether an imaging preparation procedure may be omitted or accelerated to have a shortened duration, the imaging preparation procedure comprising (i) a scanner adjustment procedure that comprises an adjustment of a center RF frequency, an estimation of an RF transmitter reference voltage, a B1 field shimming, a receive coil sensitivity mapping, and/or a B0 field shimming, and/or (ii) a preparatory scan;
when the determination of whether the imaging preparation procedure may be omitted or accelerated indicates that the imaging preparation procedure may be omitted, omit the imaging preparation procedure;
when the determination of whether the imaging preparation procedure may be omitted or accelerated indicates that the imaging preparation procedure, may be accelerated, execute the imaging preparation procedure at a standard duration or at the shortened duration that is less than the standard duration; and
execute the imaging protocol to acquire the magnetic resonance image dataset,
wherein when the center RF frequency adjustment is to be omitted, set the center RP frequency to a value determined in a previous center RF frequency adjustment, and/or (ii) when the B0 field shimming is to be omitted, use default shim settings.

14.-15. (canceled)

16. The magnetic resonance imaging system according to claim 13,
wherein the preparatory scan comprises one or more dummy scans to establish a steady slate of a magnetization and/or auto-calibration scans to estimate coil sensitivity maps.

17. The magnetic resonance imaging system according to claim 16,
wherein the processor is further configured to execute the instructions to cause the magnetic resonance imaging system to:
if the auto-calibration scans are to be omitted, estimate coil sensitivity profiles estimated from other sources, including an adjustment scan; and/or
if the auto-calibration scans are to be accelerated, adjusting a duration of the auto-calibration scans to be shorter by reducing a resolution of the auto-calibration scans.

18. The magnetic resonance imaging system according to claim 13,
wherein the scan conditions comprise the duration of the imaging protocol, a purpose of a scan of the imaging protocol, and/or a type of a scan mode of the imaging protocol.

19. The magnetic resonance imaging system according to claim 18,
wherein the predetermined reference parameters comprise one or more of:
a predetermined upper threshold of an imaging protocol duration,
a databank of predetermined possible user input commands relating to scan conditions,
a databank of purposes for different imaging protocols, and/or
a databank of predetermined types of different scan modes.

20. A non-transitory computer-readable medium having stored thereon a computer program which, when executed by a processor of a magnetic resonance imaging system for acquiring a magnetic resonance image dataset of a subject, causes the magnetic resonance imaging system to:
determine scan conditions relating to an imaging protocol that is to be carried out on the subject;
determine, based on the scan conditions and/or on predetermined reference parameters, whether an imaging preparation procedure may be omitted or accelerated to have a shortened duration, the imaging preparation procedure comprising (i) a scanner adjustment procedure that comprises an adjustment of a center RF frequency, an estimation of an RF transmitter reference voltage, a B1 field shimming, a receive coil sensitivity mapping, and/or a B0 field shimming, and/or (ii) a preparatory scan;
when the determination of whether the imaging preparation procedure may be omitted or accelerated indicates that the imaging preparation procedure may be omitted, omit the imaging preparation procedure;
when the determination of whether the imaging preparation procedure may be omitted or accelerated indicates that the imaging preparation procedure may be accelerated execute the imaging preparation procedure at a standard duration or at the shortened duration that is less than the standard duration; and
execute the imaging protocol to acquire the magnetic resonance image dataset,
wherein (i) when the center RF frequency adjustment is to be omitted, set the center RF frequency to a value determined in a previous center RF frequency adjustment, and/or (ii) when the B0 field shimming is to be omitted, use default shim settings.

21. The method according to claim 1, wherein the scan conditions comprise an image quality associated with executing the imaging preparation procedure, and
wherein the determining of whether the imaging preparation procedure may be omitted or accelerated is based upon the execution of the imaging protocol to acquire the magnetic resonance image dataset to provide images that meet a predefined threshold image quality that represents a reduction in image quality associated with executing the imaging preparation procedure at the standard duration.

22. The method according to claim 1, wherein the scan conditions comprise a duration of the imaging protocol, and
wherein the determining of whether the imaging preparation procedure may be omitted or accelerated is based upon a proportion of the duration of the imaging protocol that is required to execute the imaging preparation procedure at the standard duration.

23. The method according to claim 9, wherein the database of comparison rules comprises conditions that specify conditions per type of imaging protocol.

24. The method according to claim 1, wherein the executing the imaging protocol to acquire the magnetic resonance image dataset comprises executing a plurality of imaging protocols, and
wherein the imaging preparation procedure is omitted by using only one imaging preparation procedure prior to executing each of the plurality of imaging protocols.
